(19) United States
(12) Patent Application Publication
(10) Pub. No.: US 2016/0336504 A1
(43) Pub. Date: Nov. 17, 2016

(54) Positioning Device

(71) Applicant: XERYON, Heverlee (BE)

(72) Inventor: Jan PEIRS, Oud-Heverlee (BE)

(21) Appl. No.: 15/110,844

(22) PCT Filed: Jan. 9, 2015
(86) PCT No.: PCT/EP2015/050371

§ 371 Date: Jul. 11, 2016

(30) Foreign Application Priority Data
Jan. 9, 2014 (GB) 1400376.8
Jan. 7, 2015 (BE) 2015/5004

(51) Int. Cl. H01L 41/04

(52) U.S. Cl. CPC H01L 41/04

(57) ABSTRACT

A piezo-device for positioning a load is described. The piezo-device comprises a stator module comprising one or more piezo-electric actuator(s) oriented in a single direction. The stator module furthermore comprises at least one hinge for allowing deformation of the stator module upon actuation of the piezo-electric actuator. The piezo-device also comprises a slider or rotor module, the slider or rotor module being in contact with the stator module in at least three points of contact. The at least one hinge and the one or more piezo-electric actuator(s) are arranged in position with respect to each other for providing a tangential motion of the slider or rotor module upon actuation of the at least one piezo-actuator. The slider or the rotor are driven and supported through the points of contact.

### FIELD OF THE INVENTION

The invention relates to the field of mechanical positioning of objects. More specifically it relates to piezoelectric positioning devices and methods for positioning objects.

### BACKGROUND OF THE INVENTION

Piezoelectric positioning devices are used in a multitude of applications which require very high accuracies. The biggest limiting factor of these positioners however is the very small displacement. To counter this effect several principles of piezoelectric motors have been thought of to have limitless travel range. Three main types of motors have been designed: stepping motors, friction-inertial motors and resonant motors. Stepping motors have a high holding force but are often too slow for many applications. Resonant motors achieve high speeds at smooth motions but are rather complex to drive.

For several applications friction-inertial motors are the ideal solution. A whole list of such motors have been described by Zhang et al. in “Piezoelectric friction—inertia actuator—a critical review and future perspective” in Int. J. Adv. Manuf. Technol. (2012) published online. These motors are based on the inertia of the rotor or slider and/or on the difference between static and dynamic friction. According to the publication, two types of friction-inertial motors exist, friction driving motors and inertia driving motors. The working principle of friction driving motors is as follows: upon slow expansion/contraction of the piezo the load follows the movement because the friction force between the stator and slider is sufficiently large, causing the slider to follow the motion of the actuator. Upon fast motion of the driving actuator however, slippage may occur due to the inertia of the slider and the slider moves slightly backwards or essentially stands still, resulting in a net movement. The slider is therefore driven through asymmetrically shaped voltage signals with a slow ‘sticking’ phase and a fast ‘slipping’ phase. In inertia driving motors the load essentially stands still during the slow expansion/contraction, and is moved during the fast motion of the driving actuator.

In U.S. Pat. No. 6,940,210, an example is given of a very small rotational stick-slip piezo-motor. This motor is compact, has a good load capacity for a friction-inertial motor and is operable in extreme environments such as liquid helium temperatures, high vacuum and high magnetic fields. The motor is based on a stator with two piezos placed at the outer side of the rotor. The run-out error typically is relatively high, i.e. typically several micrometre or more. Nevertheless, for a significant number of applications, a lower run-out error is required.

Consequently, there is a need for piezoelectric based rotational positioning systems with lower run-out errors.

### SUMMARY OF THE INVENTION

It is an object of embodiments of the present invention to provide accurate positioning devices and methods.

It is an advantage of embodiments of the present invention that a particular internal design of the system allows achieving devices with high run-out accuracy. It is an advantage of embodiments of the present invention that a run-out error better than 1 μm can be achieved.

It is an advantage of embodiments of the present invention that rotational positioning devices are provided that enable rotation of the rotor and the top plate with very low radial, axial and tilt motion errors.

It is an advantage of embodiments of the present invention that positioning devices are provided that are compact.

It is an advantage of embodiments of the present invention that positioning devices are provided that provide a good load capacity with respect to other friction-inertial motors.

It is an advantage of embodiments of the present invention that positioning devices are provided that are operable in extreme environments, such as low temperatures, high vacuum and high magnetic fields. Furthermore, these devices produce negligible magnetic fields.

It is an advantage of embodiments of the present invention that positioning devices are provided that combine compactness, good load capacity and the possibility of operating in extreme environments with high run-out accuracy.

It is an advantage of embodiments according to the present invention that a kinematic suspension in the rotor/stator assembly is obtained.

It is an advantage of embodiments of the present invention that the driving function and the bearing function can be established by a single means, thus resulting in a compact design, which is also free of play.

It is an advantage of embodiments of the present invention that gaps between stator and rotor or between stator and slider are compensated for. The compensation means at the same time act as preloading mechanism.

It is an advantage of at least some embodiments of the present invention that the rotor is placed around the stator, whereby actuation can be achieved using only one piezo-stack, although embodiments are not limited thereto.

It is an advantage of embodiments of the present invention that at least one hinge provided at a predetermined position with respect to the contacts is used allowing uniform tangential traction forces.

It is an advantage of embodiments of the present invention that a mechanical solution is provided for providing pretension, resulting in a solution that is robust to shape and size deviations and to wear.

It is an advantage of embodiments that a relatively simple device is obtained for providing the accurate positioning. The simplicity of the design increases the robustness of the device as well as the ease of manufacturing.

It is an advantage of embodiments of the present invention that rotational positioning devices are provided, having a large central hole for transmitting any sort of beams or letting through any sort of cables, that enable rotation of the rotor and/or the top plate with very low radial, axial and tilt motion errors.

It is an advantage of some embodiments of the present invention that accurate positioning devices are provided, having two piezo-actuators, which increase the mechanical power output of the device (i.e. speed and/or traction).

It is an advantage of some embodiments of the present invention that rotational positioning devices are provided, having two piezo-actuators which give an extra degree of freedom to further compensate for a possible remaining run-out error, although already very small. The above objective is accomplished by a method and device according to the present invention.

The present invention relates to a piezo-device for positioning a load, the piezo-device comprising a stator module comprising one or more piezo-electric actuator(s) oriented in a single direction, the stator module furthermore comprising at least one hinge for allowing deformation of the stator module upon actuation of the piezo-electric actuator. The piezo-device also comprises a slider or rotor module, the slider or rotor module being in contact with the stator module in at least three points contact. The at least one hinge and the one or more piezo-electric actuator(s) are arranged in position with respect to each other for providing a tangential motion of the slider or rotor module upon actuation of the at least one piezo-actuator. The slider or rotor module are driven and supported through the contact points. In other words, the bearing and driving are combined resulting in a compact arrangement.

When more piezo-electric actuators are present, these typically may all be oriented in the same, single direction. The tangential motion may be an equally distributed tangential motion. It is an advantage of embodiments according to the present invention that a highly accurate positioning device can be obtained.

The arrangement of the at least one hinge and the one or more piezo-electric actuators may be such that the at least one hinge is not collinear with the single direction.

With respect to the single direction and the center of the stator module, for example in embodiments where only one piezo-electric actuator is used, the at least one hinge may be positioned at an angle in the range 35° to 55°. The angle may advantageously be 45°.

At least 1 contact may be supported through a flexible support. The flexible support may be for having a mechanical pretension between the stator and the slider or rotor module. It is an advantage of embodiments of the present invention that a pretension can be mechanically applied between the stator module on the one hand and the slider or rotor module on the other hand.

The stator module and the slider or the rotor module may be in contact in at least three points of contact.

The stator module may have contact elements and the slider or the rotor module may comprise a V-shaped inner surface for positioning the contact elements thereto, such that the plane of movement is fully determined.

The stator module and the slider or rotor module thus may comprise at least 6 positions of contact with each other. Together with the at least one flexibly suspended contact, this results in determination of 5 degrees of freedom of the motion thus leaving one degree of freedom of the motion, i.e. allowing rotation in the plane. It is an advantage of embodiments of the present invention that movement, e.g. rotation essentially is only possible in this plane. In case of rotation, rotation is also only possible around the center of the rotor.

The stator module and the slider or the rotor module may be using exactly three contact elements, each contact element providing two points of contact and wherein one contact element is flexibly connected, such that it is flexibly positioned in radial direction.

The slider or the rotor may be driven and/or supported through the at least one contact.

The piezo-device may comprise exactly one piezo-electric actuator.

The one or more piezo-electric actuator(s) may be two or more piezo-electric actuators, positioned at a distance from each other so as to create an empty space in between.

The one or more piezo-electric actuator(s) can be of the type parallel pre-stressed actuator, having the pre-stressing mechanism integrated in the stator design or as a separate piece to be placed inside the stator.

The piezo-device may have a large internal hole, for transmitting all sorts of beams or for passing through electrical or mechanical cables and wires. The slider or the rotor may be positioned in any plane parallel to the plane of movement.

The stator or the rotor may be borne externally through the application of a bearing. The bearing can be any type or combination of several types of external bearing(s), such as fluid bearings, air bearings, foil bearings, roller bearings, lubricated or non-lubricated contacting bearings. In this way the stator mainly provides the traction force.

The at least one hinge may comprise one or more flexible elements. The hinges may also be other types of hinges or a mixture of different types of hinges may be used.

Two or more stator modules may be stacked inside a single rotor to increase force and power output, with their driving tips oriented to actuate the same body.

The piezo-device may comprise a plurality of stator modules positioned in parallel in a plane parallel to the plane of movement, e.g. the plane of rotation.

The rotor may comprise a supporting element mounted to the rotor or slider for supporting a load to be moved.

The supporting element may comprise fixing means for fixing the load to the supporting element.

The piezo-device furthermore may comprise a bottom mounting structure for mounting the stator module thereto.

The rotor may have a groove facing outward and have a pretension pressing the contact elements on the stator module to the inner side of the groove.

The piezo-device may comprise more than one piezo-electric actuator whereby the more than one piezo-electric actuator may be positioned distanced from each other to create a central hole suitable for throughput of mechanical or electrical elements. The central hole may for example be adapted for allowing electrical cables to pass or beams to pass.

The stator may comprise a stator ring and the piezo-electric actuators may be positioned outside the stator ring or in a plane beneath or above the stator ring.

The device may comprise at least two piezo-electric actuators and the device furthermore may comprise a controller for imposing on the driving signals for the actuators a supplementary DC or slow varying voltage for shifting the center of the stator. It is an advantage of embodiments of the present invention that an additional active compensation for a possible remaining error can be provided by shifting the stator center, thus resulting in even further improved piezo-devices.

At least one of the one or more piezo-electric actuators may be a parallel pre-stressed actuator.

The piezo-device may be configured for operating in friction-based mode. The piezo-device alternatively may be configured for operating in any of a resonant mode or a direct mode.

The present invention also relates to a piezo-device for positioning purposes, comprising a stator module comprising one or more piezo-electric actuator(s) oriented in a single direction, the stator module furthermore comprising at least one hinge for allowing deformation of the stator module upon actuation of the piezo-electric actuator,

a slider or rotor module, the slider or rotor module being in contact with the stator module and being driven and/or supported through at least one point of contact, wherein at least one point of contact is positioned on a flexible support.

The present invention furthermore relates to an apparatus for moving a load, the apparatus comprising a first piezo-device according to any of the previous claims and at least one further actuator device for moving a load according to at least one degree of freedom.

The at least one further actuator device may also be a piezo-device, stacked in series with the first piezo-device. The present invention also relates to the use of such an apparatus.

The present invention also relates to the use of a piezo-device as described above for moving a load. The load may be a sample to be analysed.

Particular and preferred aspects of the invention are set out in the accompanying independent and dependent claims. Features from the dependent claims may be combined with features of the independent claims and with features of other dependent claims as appropriate and not merely as explicitly set out in the claims.

These and other aspects of the invention will be apparent from and elucidated with reference to the embodiment(s) described hereinafter.

### BRIEF DESCRIPTION OF THE DRAWINGS

FIG. 1 illustrates part of an exemplary rotational piezoelectric positioning device according to an embodiment of the present invention.

FIG. 2 illustrates a schematic representation and an A-A cross-sectional view of an exemplary rotor used in a rotational piezoelectric positioning device according to FIG. 1.

FIG. 3 illustrates an exemplary mounting plate for mounting samples as can be positioned on a rotor in a positioning device according to an embodiment of the present invention.

FIG. 4 illustrates the deformation of the flexibly suspended contact of a stator module when positioned in the rotor module, according to an embodiment of the present invention.

FIG. 5 illustrates the mounting elements for mounting a stator module to a mounting part, according to an embodiment of the present invention.

FIG. 6 illustrates an assembly of parallel stator modules, according to an embodiment of the present invention.

FIG. 7 illustrates a fully assembled piezo-device according to an embodiment of the present invention, including a mounting structure and mounting plate.

FIG. 8 illustrates a top view of a stator for use in an alternative piezo-device with a hole for passage of beams or for carrying through electrical wiring, according to an embodiment of the present invention.

FIG. 9 illustrates the deformation of the stator ring in the stator module, as occurs during operation of a piezo-device upon expansion of the piezo-actuator, according to an embodiment of the present invention.

FIG. 10 illustrates a top view of a stator for use in an alternative piezo-device with a hole for passage of beams or for carrying through electrical wiring, according to an embodiment of the present invention.

FIG. 11 illustrates part of a piezo-device according to an embodiment of the present invention, having a large central hole.

FIG. 12 illustrates a top view of a stator for use in an alternative piezo-device with a central hole, where the contacts face to the inner side of the device, according to an embodiment of the present invention.

FIG. 13 illustrates a view of an exemplary rotor used in a rotational piezoelectric positioning device according to FIG. 12. Furthermore, the mounting plate is integrated in this exemplary rotor.

FIG. 14 illustrates a fully assembled piezo-device according to an embodiment of the present invention, having a large central hole, including a mounting structure. The drawings are only schematic and are non-limiting. In the drawings, the size of some of the elements may be exaggerated and not drawn to scale for illustrative purposes.

Any reference signs in the claims shall not be construed as limiting the scope.

In the different drawings, the same reference signs refer to the same or analogous elements.

### DETAILED DESCRIPTION OF ILLUSTRATIVE EMBODIMENTS

The present invention will be described with respect to particular embodiments and with reference to certain drawings but the invention is not limited thereto but only by the claims. The dimensions and the relative dimensions do not correspond to actual reductions to practice of the invention.

Furthermore, the terms first, second and the like in the description and in the claims, are used for distinguishing between similar elements and not necessarily for describing a sequence, either temporally, spatially, in ranking or in any other manner. It is to be understood that the terms so used are interchangeable under appropriate circumstances and that the embodiments of the invention described herein are capable of operation in other sequences than described or illustrated herein.

Moreover, the terms top, under and the like in the description and the claims are used for descriptive purposes and not necessarily for describing relative positions. It is to be understood that the terms so used are interchangeable under appropriate circumstances and that the embodiments of the invention described herein are capable of operation in other orientations than described or illustrated herein.

It is to be noticed that the term “comprising”, used in the claims, should not be interpreted as being restricted to the means listed thereafter; it does not exclude other elements or steps. It is thus to be interpreted as specifying the presence of the stated features, integers, steps or components as referred to, but does not preclude the presence or addition of one or more other features, integers, steps or components, or groups thereof. Thus, the scope of the expression “a device comprising means A and B” should not be limited to devices consisting only of components A and B. It means that with respect to the present invention, the only relevant components of the device are A and B.

Reference throughout this specification to “one embodiment” or “an embodiment” means that a particular feature, structure or characteristic described in connection with the embodiment is included in at least one embodiment of the present invention. Thus, appearances of the phrases “in one embodiment” or “in an embodiment” in various places throughout this specification are not necessarily all referring to the same embodiment, but may. Furthermore, the particular features, structures or characteristics may be combined in any suitable manner, as would be apparent to one of ordinary skill in the art from this disclosure, in one or more embodiments.

Similarly it should be appreciated that in the description of exemplary embodiments of the invention, various features of the invention are sometimes grouped together in a single embodiment, figure, or description thereof for the purpose of streamlining the disclosure and aiding in the understanding of one or more of the various inventive aspects. This method of disclosure, however, is not to be interpreted as reflecting an intention that the claimed invention requires more features than are expressly recited in each claim. Rather, as the following claims reflect, inventive aspects lie in less than all features of a single foregoing disclosed embodiment. Thus, the claims following the detailed description are hereby expressly incorporated into this detailed description, with each claim standing on its own as a separate embodiment of this invention.

Furthermore, while some embodiments described herein include some but not other features included in other embodiments, combinations of features of different embodiments are meant to be within the scope of the invention, and form different embodiments, as would be understood by those in the art. For example, in the following claims, any of the claimed embodiments can be used in any combination.

In the description provided herein, numerous specific details are set forth. However, it is understood that embodiments of the invention may be practiced without these specific details. In other instances, well-known methods, structures and techniques have not been shown in detail in order not to obscure an understanding of this description.

Where in embodiments of the present invention reference is made to a piezo, a piezo-actuator, a piezoelectric element, or alike, reference is made to an active element, consisting of or comprising piezoelectric material and electrodes, generally in the form of a piezo-ceramic stack and allowing to change size as function of an electric field applied.

Where in embodiments of the present invention reference is made to a piezoelectric positioning device, a piezo-device or alike, reference is made to the ensemble of at least a stator and rotor and/or stator and slider, wherein typically the stator comprises piezo-actuator(s) and other mechanical elements to house the piezo-actuators and to transform the motion of this/these piezo-actuator(s) into a useful motion of a load. Additional components such as a mounting element and a load mounting element also may be part of such a device.

Where in embodiments of the present invention reference is made to a stator, reference is made to the structural part of the piezo-device used for holding the piezo-actuator(s), and containing flexible and rigid sections at well-chosen locations, to form the mechanism that transforms the deformation of the piezo-actuator(s) into a useful motion of the load.

Where in embodiments of the present invention reference is made to a hinge, reference is made to a feature in the stator with narrowed section, and therefore increased flexibility, acting as a pivot or hinge in the structure. Such a hinge may also be referred to as a flexure hinge.

Where in embodiments of the present invention reference is made to a contact, reference typically may be made to the elements of the stator module that touch the surfaces of the slider or rotor.

Where in embodiments of the present invention reference is made to the rotor or slider, reference is made to the component which is driven by the stator through relative movement of the contacts.

Where in embodiments of the present invention reference is made to “run-out error”, reference is made to the error caused by the fact that the center of the motor is not fixed during a rotational movement.

Where in embodiments of the present invention reference is made to a friction-based drive mode, reference is made to a friction-based drive mode as defined by Zhang et al. in “Piezoelectric friction—inertia actuator—a critical review and future perspective” in Int. J. Adv. Manuf. Technol. (2012) published online.

In a first aspect, the present invention relates to a piezoelectric positioning device, also referred to as a piezo-device. Positioning devices according to embodiments of the present invention advantageously work in a stick-slip mode, also referred to as friction-driving mode, although embodiments are not restricted thereto and an inertial-based drive mode, a resonant mode or direct mode also can be obtained. The positioning devices according to embodiments of the present invention are especially suitable in applications where a high accuracy is required, as they provide low radial, axial and tilt motion errors. The device may be a rotational piezo-device although embodiments are not limited thereto and for example linear piezo-devices also may be envisaged. According to embodiments of the present invention, the device comprises a stator module comprising one or more piezo-electric actuator(s) oriented in a single direction. The stator module furthermore comprises at least one hinge for allowing deformation of part of the stator module upon actuation of the piezo-electric actuator. According to embodiments of the present invention, the device also comprises a slider or rotor module, the slider or rotor module being in contact with the stator module in at least three points of contact. Typically a slider will be used for linear devices, whereas a rotor module will be used for rotational devices. According to embodiments, the at least one hinge and the one or more piezo-electric actuator(s) are arranged in position with respect to each other for providing a tangential motion of the slider or rotor module upon actuation of the at least one piezo-actuator. When slow actuation of the piezoelectric actuator(s) is induced, a tangential motion or alike of the contact(s) is created. This movement is translated to the slider or rotor module through friction in the contacts, which is called the ‘stick’-phase. Upon fast actuation of the actuator(s) however, slippage may occur due to the inertia of the slider or rotor module and the slider or rotor module essentially stands still. By providing the piezoelectric actuator with a suitable asymmetric drive signal, the slider or rotor module thus moves through stick-slip, also referred to as friction-based movement.

The slider or rotor module are both driven and supported through the contact points.

Piezo-devices which have two or more piezo-actuators can have extra degrees of freedom to compensate for remaining motion errors. In this case a DC or slowly varying voltage can be added to the different drive signals of the piezo-actuator(s). The adaptation of the drive signal can for instance lead to a small displacement or rotation of the center of the stator module. In this way, possible still remaining motion errors can be further decreased.

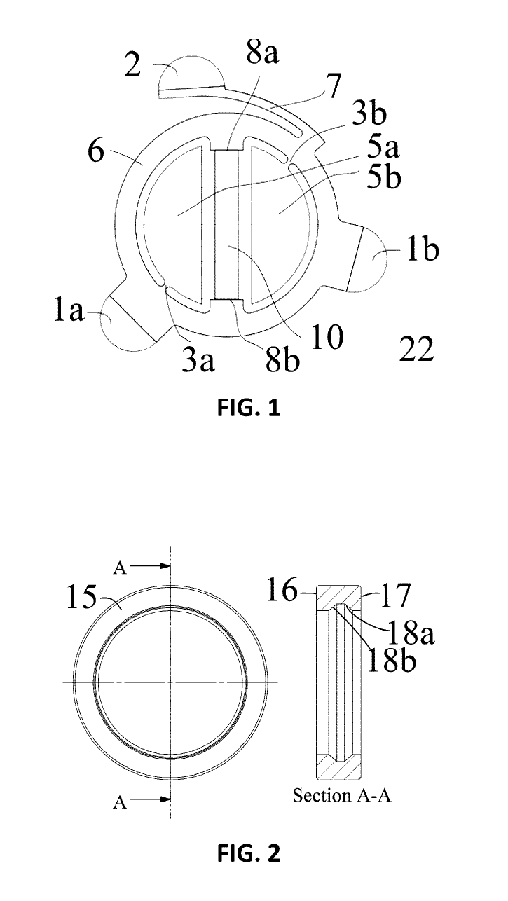

Standard and optional features of embodiments according to the present invention will now be discussed further with reference to FIG. 1 to FIG. 14, particular embodiments of the present invention not being limited thereby. Whereas the embodiments have been described with reference to friction-based drive modes, mutatis mutandis embodiments for use in inertial-based, resonant or direct driven devices also are encompassed.

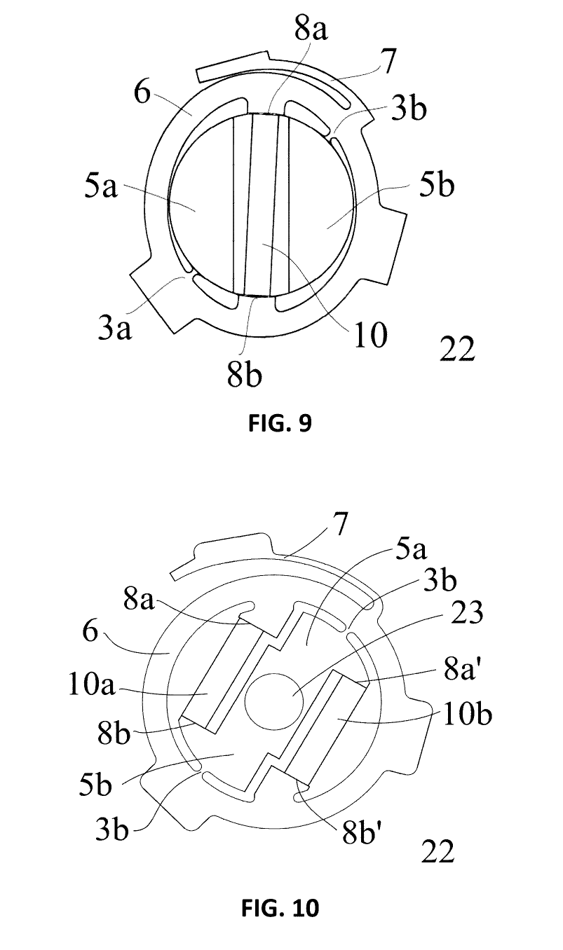

In an exemplary embodiment of the present invention, a rotational piezoelectric positioning device is described. According to the exemplary embodiment of the present invention, the positioning device comprises a stator module 22, an example shown by way of illustration in FIG. 1. The stator module 22 comprises essentially one piezo-actuator 10, which is electrically excited as to provoke the stick-slip motion. A contraction or shrinkage of the actuator 10 deforms ring 6 into an ellipse or ellipse-like shape, both referred to as ellipse in the description below for ease of explanation. It is to be noticed that in embodiments where the piezo-actuators are not positioned centrally anymore but outside or beneath the ring, typically no deformation of the ring will occur and a pure rotation will be induced. By way of illustration, the deformation of the stator, especially the stator ring 6, is shown in FIG. 9.

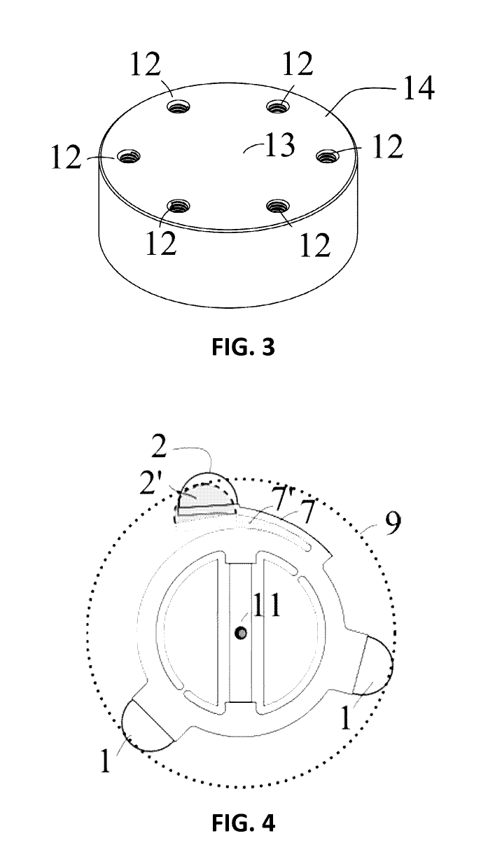

The piezo-actuator 10 contacts the stator ring 6 at interfaces 8a and 8b. The ring shaped stator is designed to have two areas where the stator is not deformed and can be fixed to the environment, i.e. area 5a and 5b. In some advantageous embodiments of the present invention, the flexure hinges 3a, 3b in the stator module 22 are placed at an angle between 35° and 55°, e.g. substantially 45°, with respect to the piezo-actuator 10 because these points are neutral points on the ellipse, in the sense that their distance to the centre remains fixed upon actuation of the piezo. The position of contacts 1a, 1b and 2 is advantageously chosen in order to have an equal tangential movement of the contacts 1a, 1b and 2 in the zone of the actual contact with the rotor 15. Contact la moves through a rotation around hinge 3a. The effective tangential translation in the contact is equal to or can be estimated as the multiplication of this rotation angle with the distance to the hinge 3a. Contact 2 follows a similar displacement, but the motion is moved with an angle in the range, 50° to 70°, preferably 60 degrees because of the flexible arm 7. Contact 1b advantageously is placed at a location of the ellipse which primarily translates in a tangential direction. In this way the tangential movements of all the contacts is substantially equal in the actual zone of contact with the rotor 15. This can e.g. for contact 1a be obtained by varying the distance between the ring and the contact points. According to the exemplary embodiment, the device also comprises the rotor 15, as shown in top view and in A-A cross-sectional view in FIG. 2. The traction force on the rotor 15 is distributed equally over the inner surface(s) 18 of the rotor 15 so that none of the contacts 1a, 1b and 2 slips during the ‘stick-phase’, or at least only very limited slip occurs. The top and bottom surfaces 16 and 17 of the rotor 15 can for instance be used to mount either a mounting plate such as depicted in FIG. 3 or a component for a measurement device such as an encoder grating. On top of the rotor 15 a mounting plate 14 is fixed which can hold a sample on the top surface 13 through one or more fixation points 12, which can be of any type. FIG. 3 shows an example of such a mounting plate 14 and this version has six screw holes as fixation points 12.

In the exemplary embodiment, at least one of the contacts 1,2 is suspended through a flexible support 7 on the stator module 22, here called a suspended contact 2. The other contact(s) is/are rigidly connected to the stator module 22 and each such contact is here referred to as a fixed contact 1. The flexible support 7 bridges the gap between stator module 22 and rotor 15 and establishes a certain preload. FIG. 4 shows the deformation of flexible support 7 and 7′ when the rotor 15 is placed over the contacts 1,2 of the stator module 22. In the deformed state the flexible support 7′ leads to a pretension force of the stator module 22 against the rotor 15. The flexible support advantageously is stiff in a driving direction and flexible in the pretension direction. In the axial bearing direction, perpendicular to the driving and pretension direction, the flexible support advantageously also is stiff. Each flexible support 7 is deformed until it reaches a position 7′ with the corresponding suspended contact point 2 moved slightly to an inward position 2′. Each flexible support 7 deforms until an equilibrium is found in forces borne by the contacts 1,2. A circle 9 with centre 11 is defined by the fixed contact(s) 1 and the deflected contact(s) 2′. The circle 9 is defined by at least three contacts 1,2. Advantageously three contacts are used, one being flexible. Three points define one plane and therefore this plane is determined kinematically. This makes sure that the rotating movement remains in one plane. If more than three contacts 1,2 are used on the stator module at least two have to be flexible contacts 2, requiring at least two flexible supports 7 for the piezo-device to remain in a kinematically determined state. Using more than three contacts (with the required flexibility in at least two contacts) can help to achieve a higher stiffness. This can be interesting to increase the load capacity or to increase the maximum frequency of the actuation signal for the piezo-device, leading to higher driving speed. The rotor 15 is essentially moved along this circle 9.

The flexible support 7 also facilitates the assembly of the rotor 15, which is positioned around the stator module 22 and in contact with the contacts 1,2. Another effect of the flexible support 7,7′ is that it automatically compensates for small imperfections in the circularity/cylindricity of the rotor surfaces 18.

In the present invention both bearing and traction function of the motor are combined in one design. The contacts 1,2 act as bearing points and also provide a force for moving the rotor 15. By combining both functions the piezo-device can be made very compact while still achieving a very good performance. Moreover, this eliminates the need for an external bearing mechanism, which is often prone to mechanical play, like in roller bearings.

The piezo-device of the exemplary embodiment can be made very small and can achieve a relatively high torque because the traction is performed at a large diameter. This high traction is combined with a good run-out error measured on the rotor 15. It can particularly be used for positioning a sample in a measurement instrument which requires the centre of the rotation 11 to be kept fixed in position. The piezo-device is an ideal solution for applications in high vacuum conditions and cryogenic temperatures. It produces no disturbing magnetic fields and the materials can be chosen not to magnetically influence the environment, e.g. electron-beams, ion-beams, X-rays, . . . .

The flexure hinges 3a, 3b in the stator module 22 are in some embodiments separated from each other by an angle of 180 degrees. Nevertheless, essentially any angle of separation can be used as long as the net movement of each contact 1,2 leads to an essentially similar traction movement. The preferred embodiment uses (a) flexure hinge(s) 3a,3b because these are free of play and friction, but any other type of hinges can be used. The position of the hinges can be varied in the radial direction or tangential direction.

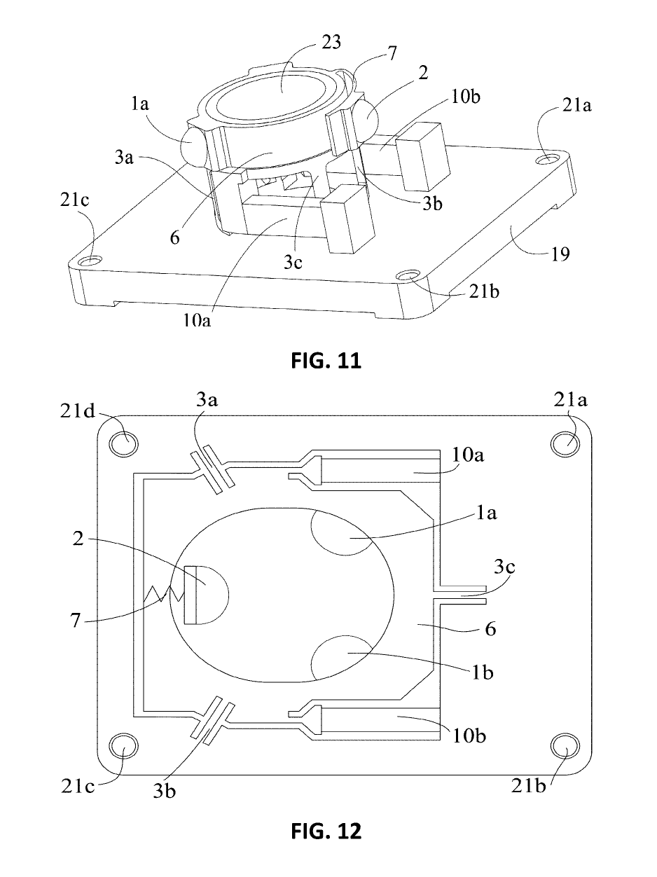

In one embodiment, the hinges 3a,3b,3c are not all located in the same plane as the stator ring 6. The stator ring 6 can for instance be connected to the mounting structure 19 through flexible rods, which act as hinges between the stator ring 6 and the bottom part 19, see FIG. 11. These rods guide the movement of the stator ring. Upon actuation of the piezo-actuators 10a,10b, the ring is moved in the desirable degree of freedom. By actuating the two piezo-actuators 10a,10b of FIG. 11 in opposite directions (this means an expansion of the first piezo-actuator 10a and a contraction of the second piezo-actuator 10b, or vice versa), the stator ring 6 will move in a purely rotational way. All of the contacts 1,2 will move in the same tangential direction and will contribute evenly to the traction of the rotor 15. The use of two piezo-actuators 10a,10b increases the mechanical output power and gives a more symmetric lay-out. A higher degree of symmetry can be beneficial for limiting the effects of thermal deformations on the motion errors. Furthermore, the use of two piezo-actuators 10a,10b can add an extra functionality to the piezo-device. By actuating the two piezo-actuators 10a,10b of FIG. 11 in the same direction, the center of the rotation can be moved with a small amount. In this way the run-out error of the rotational piezo-device can be compensated for.

Although the presented invention already leads to very small motion errors due to its mechanical design, it is possible to decrease the motion errors even further through a compensation. The phase and voltage difference of the two signals can be adjusted slightly to compensate for the still remaining motion errors. The run-out error can for instance be decreased by slightly moving the center of the stator body due to a deformation in the flexure hinges. Therefore, the run-out error can be measured with a sensor before-hand or during operation and this error can be used as an input for this additional compensation method.

All the parts can exist of materials such as (but not limited to) aluminium, titanium, beryllium copper, magnetic and nonmagnetic (stainless) steels or polymers. The motor has an open structure in the sense that air (or any gas) can be easily evacuated from the internals of the motor. Unless the application does not require it, all materials of the piezo-device are preferentially as non-magnetic as possible to have no influence on the magnetic fields of the environment.

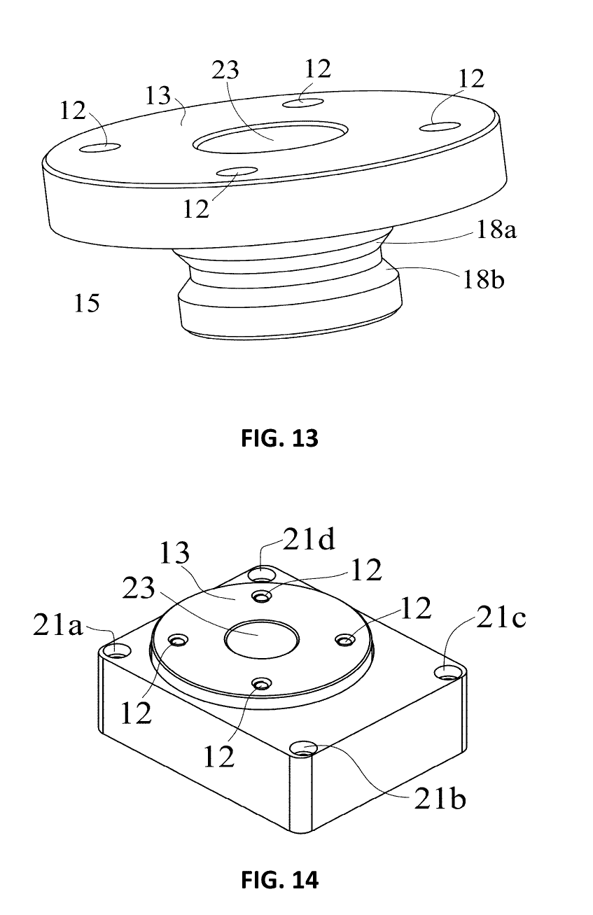

On top of the rotor 15 a mounting piece 14 can be fixed to mount an object such as for example a sample or any other type of payload. The mounting piece 14 can also be an integral part, e.g. monolithical part, of the rotor 15. Such an example is shown in FIG. 13. The mounting of the sample, to be positioned with the piezo-device, on top of the upper mounting face 13 is achieved through one or more fixation element(s) 12, for instance bolts, press fits, glue or other fasteners or fastening methods.

All the fixation elements 12 or even structural elements can include some damping materials (like for instance rubber) to dampen the vibrations coming from the actuator(s) to avoid excessive vibration of the sample and/or of the environment on which the piezo-device is mounted. The piezo-device can be easily scaled (isometrically or not) without hampering the operating principle of the device. Also the width of the stator module 22 and/or of the rotor 15 can be changed arbitrarily.

The rotor 15 has an essentially V-shaped inner surface in which each contact 1,2 makes contact at both faces of the V-shaped surface 18a and 18b. The faces of the V in the V-shape can have an arbitrary angle of 0 to 90 degrees with respect to each other and an arbitrary distance between the two. This groove in the rotor 15 does not necessarily need to have a V-shape: its shape does not need to be symmetric and one or both of the contacting surfaces 18a, 18b can have a (double-)curved inner surface too. The contacts 1a, 1b, 2 define the position of the centre 11 of the rotor 15. The centre of macroscopic rotation of the rotor 15 substantially equals the centre 11 of the rotor 15. This means that the contacts 1,2 also function as bearing points, next to the fact that they transmit a traction force. This is similar to a four-point contact ball bearing, but with the balls being split in half and fixed on top of the stator module 22 so that only the rotor 15 can slip over the contacts 1,2. In principle also other types of ball or cylindrical bearings can be used in a similar reasoning for this purpose, like for instance singular or double row angular contact ball bearings, deep groove ball bearings, self-aligning bearings, thrust bearings, cylindrical roller bearings, needle roller bearings, tapered roller bearings, spherical roller bearings, and similar types.

In an advantageous embodiment three contacts 1a, 1b, 2, exactly three in number, are chosen, each contact 1,2 having two actual contacting points with the groove, one on inner surface 18a and one on inner surface 18b. One contact has an elastic suspension in the radial direction. This fixes the centre of rotation 11 and the plane of rotation at the same time and in a kinematic way. Thus five degrees of freedom of rotor 15 are fixed in a kinematic way: the three translational degrees of freedom and two tilting degrees of freedom. Only a rotational movement around the central axis of the rotor 15 is allowed through this configuration. It also assures that the rotation axis is perpendicular to the groove.

The wear of the inner surface(s) 18 of the rotor 15 can be reduced by the application of coating materials or lubricants. These coatings can also catch particles generated by wear of the contacts and groove, as to reduce the contamination in clean environments, for instance in vacuum chambers of electron microscopes.

In some examples, embodiments of the present invention not being limited thereby, the rotor 15 can also be borne externally with a rotary bearing, such as: an air-bearing, hydrostatic bearing, a lubricated/dry sliding bearing, a roller bearing or any other type of bearing. The stator module then only performs a traction force and the contacts 1,2 are not used in a similar way as the purpose of a bearing.

In another implementation the rotor 15 incorporates a flexible inner ring right beneath the contacting surface(s). This flexibility can be used together with or in replacement of the flexibility of the one or more flexible supports 7 of the contacts 1,2. The rotor 15 can also consist of two or more parts which are connected through one or more spring(s), to provide flexibility in said rotor.

A grating structure can easily be mounted on the upper or lower surfaces 16,17 of the rotor 15 to function as part of a position encoder. Also other types of encoders or position sensors can be used, for instance based on resistive, magnetic or optical principles.

In a preferred embodiment, the piezo-actuator 10 is preloaded by ring 6, which is elastically deformed before insertion of piezo-actuator 10, as to provide a continuous normal compressive force on both piezo-actuator ends. This preload keeps the piezo-actuator 10 in place and under compression. Also other pretensioning elements can be used, as for instance a type of fastening bolt placed in parallel with the piezo-actuator, or inserted through a hole in a hollow piezo-actuator (tube). Or any parallel combination of one or more piezo-actuators and one or more pretensioning elements can be used. The piezo-actuator can also be fixed with glue or similar connecting material. The piezo-actuator can also be of type parallel pre-stressed actuator, having a feature to induce a pre-stress already before mounting the piezo-actuator inside the stator body. Such a feature can also be integrated in the stator body itself.

In an advantageous embodiment, the piezo-actuator 10 is a stack-type actuator because of the relatively big displacement it can generate compared to other piezo-actuator types for a given voltage. But also monolithic piezo-components can be used at the expense of higher voltages. Other implementations of piezo-materials can be used such as piezoelectric plates which are fixed on the surface of a central flexible part replacing the original part 10, and extending through the longitudinal (33) direction, the transversal (31) direction or the direction wherein shear effect (51) occurs. The actuators can for example also be actuators of the group consisting of piezoelectric actuators (including piezo benders), electrostrictive actuators and magnetostrictive actuators. The piezo-actuator 10 can be replaced by two (or more) piezo-actuators, placed in parallel or in series, with a spacing and/or intermediary part in between the two (or more) piezo-actuators. This spacing or a hole in the intermediary part can be beneficial for transmitting beams (e.g. of optical nature), electrical wiring or cables through the piezo-device. Such a spacing or hole can be created by placing the piezo-actuator(s) 10 in a plane beneath or above the stator ring 6, of which an example is shown in FIG. 11. In this way a much larger spacing can be created. Another example of an embodiment of the piezo-device, having a large central spacing, is shown in FIG. 12. In this case the piezo-actuators are still in the same plane as the stator ring 6, but are placed at the outer side of the stator ring 6.

In the case of a single piezo-actuator, this actuator can be placed outside of the centre 11 of the stator body 22, with an extension of one of the stator-to-piezo interfaces 8. In this extension a hole can be made for transmitting beams (e.g. of optical nature), electrical wiring or cables through the centre of the piezo-device.

FIG. 8 illustrates an embodiment wherein one of the end faces is shifted towards the top and where a hole 23 is indicated. Such a hole may be used for transmitting electromagnetic, optical, X-ray . . . waves, as well as for example for passage of electrical wires and cables.

In some embodiments, the piezo-actuator 10 can have one of the voltage poles connected to the stator so that only one wire has to be used to apply a differential voltage signal to the actuator. As indicated above, the piezo-device typically is designed to work in a stick-slip mode. However it is also possible to use the piezo-device, simultaneously or subsequently, in other working modes, such as a resonant mode or a direct mode. In the resonant mode the piezo-actuator is excited at higher frequencies which coincide with a resonance of the structure. In this way higher velocities can be reached. In the direct mode a (slowly varying) DC signal is applied on the piezo-actuator in order for it to rotate rotor 15 over a short stroke without slipping, with the stroke limited by the maximal stroke of the piezo-actuator. With the direct mode it is possible to position the rotor with very high accuracy and very high resolution, and displacement quasi proportional to the applied voltage.

The drive speed and traction force of the relative motion between the stator module 22 and said rotor 15 is controllable by changing the shape, frequency, voltage difference and slew-rate of the applied voltage signal, a principle well known by the person skilled in the art.

Also the friction and pretensioning force(s) between the contacts 1,2 and the rotor inner surfaces 18a,b may be tuned, as these forces are significantly affected by the choice of the dimensions of the flexible support 7 and can be altered slightly to improve the performance of the piezo-device.

In some embodiments, the flexible support 7 is an integral part of the stator ring 6. The flexible support 7 can be attached to the stator body 6 using more than one arm. The most important function of the flexible support 7 is that it works as a mechanical spring. This is shown schematically in FIG. 12. In some embodiments the flexible support 7 can be a separate piece which is attached to the stator body 6.

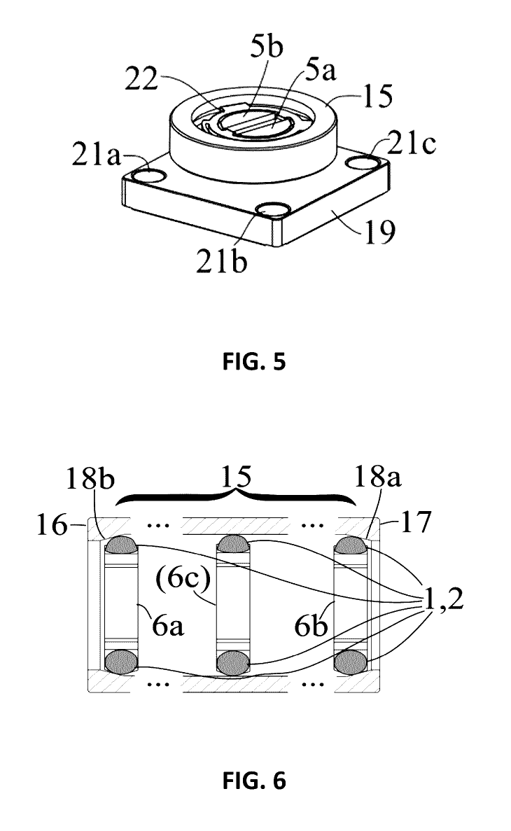

In some embodiments, the stator module 22 may incorporate one or more mounting features (such as a simple flange) to position the motor with respect to its environment within certain tolerances regarding position and orientation. In the embodiment shown in FIG. 5, the bottom plane of mounting structure 19 is parallel with the plane defined by contacts 1,2 to assure that rotor 15 turns in a plane parallel to said bottom plane. In the same embodiment, the top surface of mounting plate 14 is made parallel with the plane of the groove formed by surfaces 18a and 18b in rotor 16. Both measures guarantee that the top mounting surface 14 of the piezo-device rotates in a plane parallel to the bottom mounting surface of the stator, and without a wobble.

The contact(s) 1,2 can be of any material type, but preferably the material is a ceramic one to reduce the wear on the stator module 22. The contacts 1,2 can be an integral part of the stator module 22 itself, excluding the need for assembling separate contact point(s) 1,2 on top of the module. In this case the contacts 1,2 are left out, but the contact now occurs between the outer points of the stator module (which in fact replace the external contacts 1,2) and the inner surface(s) 18 of the rotor 15. Each contact 1,2 preferably has a shape as a part of a sphere or sphere-like surface, but can essentially have any kind of shape, such as a part of a cylinder or any other type of shape. The contacts 1,2 can also be of a full sphere or sphere-like object. The angular positions of the contacts 1,2 are preferably, but not necessarily, symmetric along the outer perimeter of the stator module 22.

The fixation of the stator module 22 to the bottom mounting part 19, which may be part or may be outside the positioning device, can be realized in a number of ways.

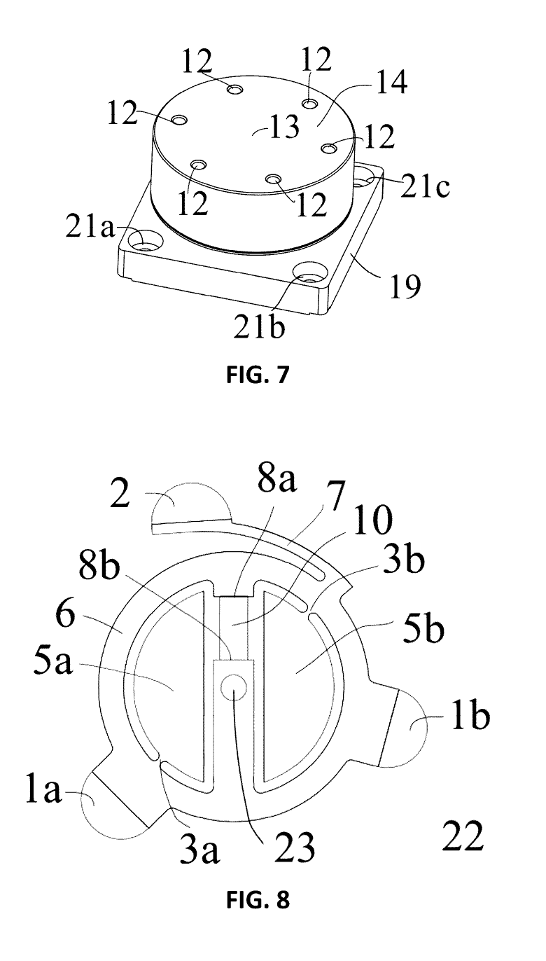

The mounting structure 19 may be provided with one or more fixation features such as for example fixation hole(s) 21 for fixation purposes, such as bolts. An example of such a mounting structure with a mounting plate positioned thereon is shown in FIG. 7. Again, the fixation of this part can be of any other type, such as for instance the use of rivets, glue, press fits or other fasteners or fastening methods.

In an alternative embodiment, mounting structure 19 and stator module 22 can be produced as a single monolithic part.

In some embodiments, two or more of said piezo-devices can be assembled in series. For instance a L-shaped piece can be mounted on top of 1 piezo-device and the second piezo-device is then mounted on top of this L-part. This can also be done in more than two degrees of freedom, stacking more piezo-devices together.

Two or more of said stator modules 6 can be assembled in parallel to form 1 thicker piezo-device. It is to be noticed that in principle the parallel stators do not need to have the same orientation: they can be rotated with respect to each other in the rotation plane of the rotor. An example of such parallel assembly is shown in FIG. 6 (the dots indicate that multiple stators can be fit in between the drawn stator modules). When two or more stator modules 6 are placed in parallel a new design of the rotor 15 is used, for instance with a wider distance in between the contacting faces 18a,b of the V-shaped cross-section. Nevertheless other designs are also possible. The most upper and lower stator modules 6 may, but not necessarily will, contact one of the two surfaces of the V-shaped cross-section, while other intermediate stators, if present in the design, act on a cylindrical surface. Other examples may be a device with one stator being in contact with a V-shaped groove where the other stators are in contact with a cylindrically shaped groove, a device with one stator being in contact with a cylindrically shaped groove and the other stators with a V-shaped groove. Each stator thereby may have its own piezo. The traction force is essentially multiplied by the number of stator modules 6 in the whole piezo-device.

Also, several stator modules 6 can be positioned in parallel, not axially as illustrated in FIG. 6, but in a plane parallel to the plane of rotation. In this way, several stator modules 6 drive the rotor 22, but only through one contact per stator module 6. This can be advantageous when the rotor has a relatively large radius.

Whereas in the above exemplary embodiments, a positioning device has been described wherein the contacts are pressed in a groove that is facing inward, embodiments are not limited thereto and the system could be adapted so as to provide a groove facing outward (in the rotor) and having a pretension pressing the contacts (on the stator module) to the inner side of this groove. FIG. 12 and FIG. 13 show an exemplary embodiment of such a stator module and rotor respectively. It is easier to produce a rotor of FIG. 13, as compared to a rotor of FIG. 2. FIG. 14 shows an example of a fully assembled device according to an embodiment, wherein the contacts of the stator are facing the groove at the outer side of the rotor.

Whereas in the above exemplary embodiments the stator module 6 is stated to be fixed to the environment and the rotor 15 is being moved rotationally, also the so-called rotor can be fixed to the environment such that the stator module is rotated during operation of the device.

Furthermore, whereas the above exemplary embodiments have been described as a rotational piezoelectric positioning device, embodiments of the present invention also relate to a linear piezoelectric device. In such embodiments, the rotor is replaced by a slider with two parallel V-grooved surfaces whereby the stator module will drive the slider in a linear way. At least two contacts are in contact with one linear V-groove, while at least one contact touches a second linear V-groove. One or more of the contacts can be suspended through a flexible arm, similar to the rotational embodiments of the present invention. In another embodiment, four contacts may be used, two for each groove. The two linear V-grooves can be incorporated in one piece. In this case the flexibility does not necessarily need to be situated beneath one or more of the contacts, but it can be integrated in the piece which comprises both V-grooves. This gives a very compact design of the linear piezo-drive. Other features and advantages may be obtained by mutatis mutandis implementing features of the rotational embodiments.

In another aspect, the present invention also relates to an apparatus that comprises one or more of the piezo-devices according to embodiments of the present invention and that is controllable to allow the simultaneous or subsequent use of these piezo-devices to position the apparatus in one or more degrees of freedom. Such apparatus may, in some embodiments, further comprise a mobile unit, having one or more linear and/or rotational actuators, for instance a xyz-positioning unit. These linear actuators can position one or more axes of rotation. The actuators in each of these motors can be actuators from the group consisting of piezoelectric actuators, electrostrictive actuators and magnetostrictive actuators. Features and advantages of apparatus according to embodiments of the present invention may correspond with features and advantages of position devices according to embodiments of the first aspect.

In still another aspect, the present invention relates to the use of a device according to an embodiment of the first aspect of the present invention or an apparatus according to the second aspect of the present invention for moving a load.

1-27. (canceled)

28. A piezo-device for positioning a load, the piezo-device comprising
a stator module comprising one or more piezo-electric actuator(s) oriented in a single direction, the stator module furthermore comprising at least one hinge allowing deformation of the stator module upon actuation of the piezo-electric actuator,
a slider or rotor module, the slider or rotor module being in contact with the stator module in at least three points of contact,
wherein the at least one hinge and the one or more piezo-electric actuator(s) are arranged in position with respect to each other for providing a tangential motion of the slider or rotor module upon actuation of the at least one piezo-actuator, the slider or the rotor is adapted to be driven and supported through the points of contact.

29. A piezo-device according to claim 28, wherein the arrangement of the at least one hinge and the one or more piezo-electric actuators is such that the at least one hinge is not collinear with the single direction.

30. A piezo-device according to claim 28, wherein at least one contact is supported through a flexible support.

31. A piezo-device according to claim 28, wherein the stator module has contact elements and wherein the slider or the rotor module comprises a V-shaped inner surface for positioning the contact elements thereto, such that the plane of movement is fully determined and/or wherein the stator module and the slider or the rotor module are using exactly three contact elements, each contact element providing two points of contact and wherein one contact element is flexibly connected, such that it is flexibly positioned in radial direction.

32. A piezo-device according to claim 28, wherein the piezo-device comprises exactly one piezo-electric actuator.

33. A piezo-device according to claim 29, wherein, with respect to the single direction and the center of the stator module, the at least one hinge is positioned at an angle in the range 35° to 55°.

34. A piezo-device according to claim 28, wherein the one or more piezo-electric actuator(s) are two or more piezo-electric actuators, positioned at a distance from each other so to create an empty space in between.

35. A piezo-device according to claim 28, wherein the slider or the rotor is positioned in any plane parallel to the plane of movement and/or wherein the stator or the rotor is borne externally through the application of a bearing.

36. A piezo-device according to claim 28, wherein the at least one hinge comprises one or more flexible elements and/or wherein two or more stator modules are staked inside a single rotor to increase force and power output, with their driving tips oriented to actuate the same body.

37. A piezo-device according to claim 28, wherein the piezo-device comprises a plurality of stator modules positioned in parallel in a plane parallel to the plane of movement, e.g. the plane of rotation.

38. A piezo-device according to claim 28, wherein the rotor comprises a supporting element mounted to the rotor or slider for supporting a load to be moved.

39. A piezo-device according to claim 38, wherein the supporting element comprises fixing means for fixing the load to the supporting element.

40. A piezo-device according to claim 28, wherein the piezo-device furthermore comprises a bottom mounting structure for mounting the stator module thereto, and/or wherein the rotor has a groove facing outward and has a pretension pressing contact elements on the stator module to the inner side of the groove.

41. A piezo-device according to claim 28, wherein the piezo-device is configured for operating in a friction-inertial based mode and/or wherein the piezo-device is configured for operating in any or a resonant or a direct mode.

42. A piezo-device according to claim 28, wherein the piezo-device comprises more than one piezo-electric actuator, and whereby the more than one piezo-electric actuator are positioned distanced from each other to create a central hole suitable for throughput of mechanical or electrical elements.

43. A piezo-device according to claim 28, wherein the stator comprises a stator ring and wherein the piezo-electric actuators are positioned outside the stator ring or in a plane beneath or above the stator ring and/or wherein at least one of the one or more piezo-electric actuators is a parallel pre-stressed actuator.

44. A piezo-device according to claim 28, the device comprising at least two piezo-electric actuators and the device furthermore comprising a controller for imposing on the driving signals for the actuators a supplementary DC or slow varying voltage for shifting the center of the stator.

45. An apparatus for moving a load, the apparatus comprising a first piezo-device according to claim 28 and at least one further actuator device for moving a load according to at least one degree of freedom.

46. An apparatus according to claim 28, wherein the at least one further actuator also is a piezo-device, stacked in series with the first piezo-device.

47. The use of a piezo-device according to claim 28, for moving a load.
